(19) United States
(12) Patent Application Publication
(10) Pub. No.: US 2024/0234619 A1
(43) Pub. Date: Jul. 11, 2024

(54) METHOD FOR MANUFACTURING TRANSPARENT THIN FILM TRANSISTOR-BASED PHOTOSENSITIVE DEVICE

(71) Applicant: National Yang Ming Chiao Tung University, Hsinchu City (TW)

(72) Inventors: Po-Tsun LIU, Hsinchu City (TW); Yu-Chuan CHIU, Taoyuan City (TW); Jia-Lin HUANG, Kaohsiung City (TW)

(21) Appl. No.: 18/406,630

(22) Filed: Jan. 8, 2024

(30) Foreign Application Priority Data
Jan. 11, 2023 (TW) 112101153

(51) Int. Cl. H01L 31/113; H01L 31/032; H01L 31/20

(52) U.S. Cl. CPC H01L 31/1136; H01L 31/032; H01L 31/20

(57) ABSTRACT

A method for manufacturing a transparent thin film transistor-based photosensitive device includes preparing a semiconductor substrate unit including a gate electrode layer, forming a gate insulator layer by depositing a high dielectric constant material using plasma-assisted atomic layer deposition to cover the gate electrode layer, forming a sensing channel layer made of an indium oxide-based material on the gate insulator layer in a position corresponding to the gate electrode layer by sputtering and doping nitrogen into the sensing channel layer, and forming a source electrode and a drain electrode on two opposite end portions of the sensing channel layer, respectively.

### CROSS-REFERENCE TO RELATED APPLICATION

This application claims priority to Taiwanese Invention Patent Application No. 112101153, filed on Jan. 11, 2023, the entire disclosure of which is incorporated by reference herein.

### FIELD

The disclosure relates to a method for manufacturing a photosensitive device, and more particularly to a method for manufacturing a transparent thin film transistor-based photosensitive device.

### BACKGROUND

With the rapid development of flat panel displays and wearable electronic devices, in addition to having high resolution of these products, having more added functions is also expected by the customers. Cellphones are the most familiar tech products to people, and due to an increasing awareness of data protection, a higher level of fingerprint recognition technology is also required.

Common fingerprint readers include three main types: capacitive, ultrasonic, and optical.

Capacitive fingerprint readers have the advantages of low power consumption and low cost, and are easy to manufacture. They were first used on cellphones at large scale. However, a conventional capacitive fingerprint reader occupies a large area of a screen, and cannot be combined with the screen, so it cannot be used as an in-display fingerprint reader, which reduces the screen area and increases the cellphone size.

Ultrasonic fingerprint readers may be used as in-display fingerprint readers, but manufacturing cost thereof is high, the voltage of their driver circuits is high and the driver circuits are more complex, and therefore they are not suitable for mass production.

Currently, the mainstream sensor of an optical fingerprint reader includes a complementary metal-oxide-semiconductor field-effect transistor (CMOSFET) and a photodiode.

However, the CMOSFET is manufactured by using single crystal silicon, which is costly, and the process thereof is also not compatible with that of a display panel, so an area for fingerprint recognition is usually limited. A conventional photodiode has low responsivity and sensitivity, so in applications, a photodiode is required to have a large area and needs to cooperate with a signal amplifier so as to ensure accuracy of the signal. The size of the photodiode limits the resolution of fingerprint recognition, and the manufacturing process thereof is not compatible with that of the display panel.

Another common sensor of the optical fingerprint reader is an optical transistor, which has a thin film transistor (TFT) structure, and is highly compatible with the manufacturing process of the display panel.

A channel material of a phototransistor may include amorphous silicon, polycrystalline silicon, and metal oxide semiconductor. Amorphous silicon has a lower responsivity to light, and may not be applied to advanced high resolution displays due to having lower charge carrier mobility. Polycrystalline silicon is costly, and typically involves laser crystallization and doping activation, so it is not a good idea to be used for manufacturing large areas.

### SUMMARY

Therefore, an object of the disclosure is to provide a method for manufacturing a transparent thin film transistor-based photosensitive device that can alleviate at least one of the drawbacks of the prior art.

According to the disclosure, the method includes:

preparing a semiconductor substrate unit including a gate electrode layer;

forming a gate insulator layer by depositing a high dielectric constant material using plasma-assisted atomic layer deposition to cover the gate electrode layer;

forming a sensing channel layer made of an indium oxide-based material on the gate insulator layer in a position corresponding to the gate electrode layer by sputtering, and doping nitrogen into the sensing channel layer; and

forming a source electrode and a drain electrode on two opposite end portions of the sensing channel layer, respectively.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic view illustrating an embodiment of a transparent thin film transistor-based photosensitive device according to the present disclosure.

FIG. 2 is a graph showing a relationship between voltage of a gate electrode and current of a drain electrode, which illustrates a dark current and a photocurrent of a sensing channel layer of the transparent thin film transistor-based photosensitive device that was not subjected to nitrogen annealing.

FIG. 3 is a graph showing a relationship between voltage of the gate electrode and current of the drain electrode, which illustrates the dark current and the photocurrent of the sensing channel layer of the transparent thin film transistor-based photosensitive device that was not subjected to nitrogen annealing.

FIG. 4 is a graph showing a relationship between voltage of the gate electrode and current of the drain electrode, which illustrates the dark current and the photocurrent of the sensing channel layer of the transparent thin film transistor-based photosensitive device that was subjected to nitrogen annealing.

FIG. 5 is a graph showing a relationship between voltage of the gate electrode and current of the drain electrode, which illustrates the dark current and the photocurrent of the sensing channel layer of the transparent thin film transistor-based photosensitive device that was subjected to nitrogen annealing.

FIG. 6 is a Tauc plot graph of optical bandgap energy for the sensing channel layer of the transparent thin film transistor-based photosensitive device that was not subjected to nitrogen annealing.

FIG. 7 is a Tauc plot graph of the optical bandgap energy for the sensing channel layer of the transparent thin film transistor-based photosensitive device that was subjected to nitrogen annealing.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

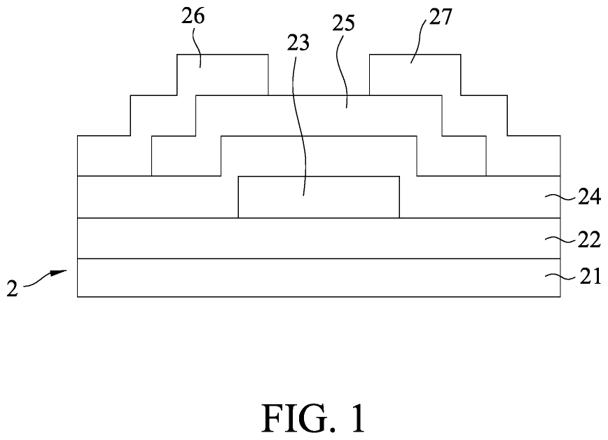

Referring to FIG. 1, an embodiment of a transparent thin film transistor-based photosensitive device of the present disclosure is suitable for application in, for example, an optical fingerprint recognition technique. The transparent thin film transistor-based photosensitive device includes a semiconductor substrate unit 2 that includes a gate electrode layer 23, a gate insulator layer 24 that is disposed on the gate electrode layer 23, a sensing channel layer 25 that is disposed on the gate insulator layer 24, and a source electrode 26 and a drain electrode 27 that are spaced apart from each other and disposed on the sensing channel layer 25.

Specifically, the semiconductor substrate unit 2 further includes a substrate 21 and a buffer layer 22 disposed on the substrate 21, and the gate electrode layer 23 is disposed on the buffer layer 22. The gate insulator layer 24 covers the gate electrode layer 23, and is made of a high dielectric constant (high-κ) material. The sensing channel layer 25 is made of an indium oxide-based material, and is disposed on the gate insulator layer 24 in a position corresponding to the gate electrode layer 23. The source electrode 26 and the drain electrode 27 are formed on two opposite end portions of the sensing channel layer 25, respectively.

Specifically, the transparent thin film transistor-based photosensitive device (may be abbreviated as the photosensitive device hereafter) of the embodiment of the present disclosure is manufactured by the following steps.

First, a silicon (Si) substrate is used as the substrate 21, silicon dioxide (SiO₂) is deposited on the substrate 21 as the buffer layer 22, and the gate electrode layer 23 made of molybdenum (Mo) is formed on the buffer layer 22, thereby preparing the semiconductor substrate unit 2. The process of forming the buffer layer 22 and the gate electrode layer 23 by deposition is well known in the art and the details thereof are omitted herein.

It should be noted that the substrate 21 may be made of a semiconductor material, a glass material, a plastic material, etc. that may be processed under low temperature (lower than 250° C.). In this embodiment, the substrate 21 is made of the semiconductor material of silicon, and the buffer layer 22 is made of silicon dioxide. Materials suitable for making the gate electrode layer 23 may include molybdenum (Mo), titanium (Ti), palladium (Pd), tungsten (W), cobalt (Co), chromium (Cr), copper (Cu), nickel (Ni), tantalum (Ta), platinum (Pt), gold (Au), aluminum (Al), tungsten titanium (TiW), titanium nitride (TiN), tantalum nitride (TaN), etc. In this embodiment, the gate electrode layer 23 is made of molybdenum (Mo).

Then, the gate insulator layer 24 is formed by depositing a high dielectric constant material using plasma-enhanced atomic layer deposition (ALD) technique to cover the gate electrode layer 23, and then is subjected to an annealing process to repair an incomplete bonding in the gate insulator layer 24 by high temperature and oxygen diffusion to thereby achieve a desired high dielectric constant value.

In this embodiment, use of the plasma-enhanced ALD for forming the gate insulator layer 24 may ensure quality and stability of the gate insulator layer 24, and may accurately control a thickness of the gate insulator layer 24, thereby increasing ability of the gate electrode layer 23 to control channel charge current and decreasing an off current, so as to reduce power consumption of the photosensitive device while on standby and to increase a signal-to-noise ratio of the photosensitive device.

In addition, the annealing process to which the gate insulator layer 24 is subjected is not particularly limited, and may be, for example, furnace tube annealing, rapid thermal annealing (RTA), microwave annealing, or laser annealing. In this embodiment, furnace annealing is used.

In this embodiment, the high dielectric constant material suitable for making the gate insulator layer 24 includes hafnium dioxide (HfO₂), aluminum oxide (Al₂O₃), zirconium dioxide (ZrO₂), hafnium zirconium oxide (HfZrO₂), titanium oxide (TiO₂), tantalum pentoxide (Ta₂O₅), or combinations thereof. In this embodiment, the gate electrode layer 23 is made of hafnium oxide (HfO₂) and has a thickness smaller than 15 nm.

Since a theoretical value of the dielectric constant (κ) of hafnium dioxide is approximately 25, in corporation with its thickness of 15 nm, the C-value of hafnium dioxide is approximately ten times of that of a conventional insulating layer. Furthermore, hafnium dioxide may greatly reduce operating voltage, increase control ability of the gate electrode layer 23, and reduce leakage current of the photosensitive device in a turn-off state, thereby reducing power consumption and increasing the signal-to-noise ratio of the photosensitive device.

Then, the sensing channel layer 25 made of the indium oxide-based material (e.g., an amorphous indium zinc oxide (IZO) material) is formed on the gate insulator layer 24 in a position corresponding to the gate electrode layer 23 by sputtering, and nitrogen is then doped into the sensing channel layer 25. The manner of preparing the sensing channel layer 25 is quite various. For example, the sensing channel layer 25 may be formed by directly depositing an indium zinc oxide film, by co-sputtering a zinc oxide target and an indium oxide target, or by sputtering an indium film and a zinc film followed by oxidizing the indium film and the zinc film.

Since the quantity of defects of the indium zinc oxide film directly impacts its conductivity properties and its sensing ability of visible light, to prepare the indium zinc oxide film of high quality, in the present embodiment, an indium zinc oxide target of high purity is used. The indium zinc oxide target may have a ratio of In₂O₃ to ZnO of 9:1. The gate insulator layer 24 may be formed by the indium zinc oxide target through sputtering deposition. The deposition may be conducted under a low speed condition, and the sensing channel layer 25 thus formed may have a thickness ranging from 2 nm to 10 nm. In this embodiment, the transparent thin film transistor-based photosensitive device has a channel width of 80 μm, a channel length of 5 μm, and a channel thickness of 10 nm. Since sputtering is used in this embodiment, the sensing channel layer 25 prepared thereby is not only large in area, but also has good quality and high uniformity, and may be integrated with a conventional panel and a wearable device.

Additionally, the manner of doping nitrogen into the sensing channel layer 25 is not particularly limited. The sensing channel layer 25 may be doped with nitrogen by in-situ introduction of nitrogen when the sensing channel layer 25 is formed. That is to say, when forming the sensing channel layer 25 by deposition, nitrogen is simultaneously introduced so as to form the sensing channel layer 25 doped with nitrogen. Alternatively, the sensing channel layer 25 may be doped with nitrogen by subjecting the sensing channel layer 25 to nitrogen annealing after being formed. In this embodiment, nitrogen annealing is performed so as to dope nitrogen into the sensing channel layer 25. In this embodiment, each of the gate insulator layer 24 and the sensing channel layer 25 may be subjected to supercritical carbon dioxide fluid technology to enhance a dielectric property thereof by being placed in a high pressure reactor where carbon dioxide is heated to a temperature over 40° C. and under a pressure over 1500 psi such that the carbon dioxide becomes a supercritical fluid.

In this embodiment, the sensing channel layer 25 includes amorphous indium oxide, amorphous indium zinc oxide, amorphous indium tungsten oxide, amorphous indium tungsten zinc oxide, amorphous indium tin oxide, amorphous indium tin zinc oxide, or combinations thereof.

In this embodiment, the sensing channel layer 25 includes the amorphous indium zinc oxide material instead of an amorphous indium gallium zinc oxide material that is currently in use, so that the sensing channel layer 25 has a higher carrier mobility (over 20 cm²/V-s), and may be used as a main component in a pixel circuit. Additionally, the amorphous indium zinc oxide material has a sensitivity to light in the visible spectrum, and an extremely high optical responsivity to blue light. The sensing channel layer 25 may undergo nitrogen annealing to change and adjust the quantity and distribution of defects therein, to lower its bandgap, and to increase the spectral range and amplitude of its responsivity, thereby further increasing the responsivity of the amorphous indium zinc oxide material to green light, and improving electrical and light sensing performance of the photosensitive device. This additionally satisfies the requirement of in-display fingerprint readers, which calls for high responsivity and high signal-to-noise ratio to blue light and green light under low lighting conditions.

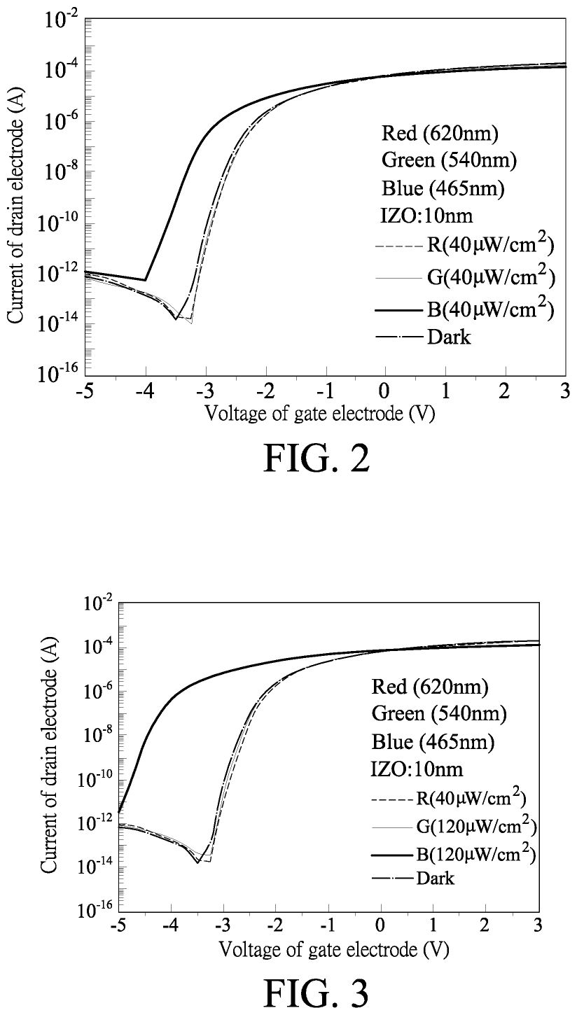

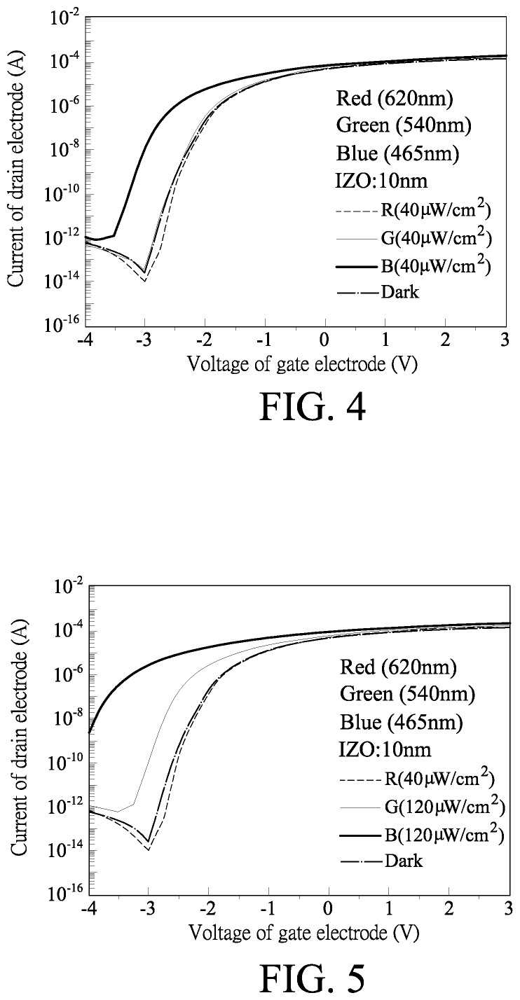

Referring to FIGS. 2 to 5, FIGS. 2 and 3 are graphs illustrating respectively a dark current and a photocurrent of the sensing channel layer 25 that was not annealed. FIG. 4 and FIG. 5 are graphs illustrating respectively a dark current and a photocurrent of the sensing channel layer 25 that was annealed by nitrogen at 200° C. for half an hour. It can be seen from the graphs that when the photosensitive device was exposed to blue light and green light (40 uW/cm² to 120 uW/cm²), the photosensitive device that was not annealed by nitrogen had a lower responsivity to blue light (small curve shift), but not to green light (as shown in FIGS. 2 and 3). The photosensitive device that was subjected to nitrogen annealing exhibited an apparent onset voltage drift (as shown in FIGS. 4 and 5). Therefore, the experimental results satisfy the expected objective of the present disclosure that the indium zinc oxide film doped with nitrogen may increase the sensitivity and responsivity of the sensing channel layer 25 to light.

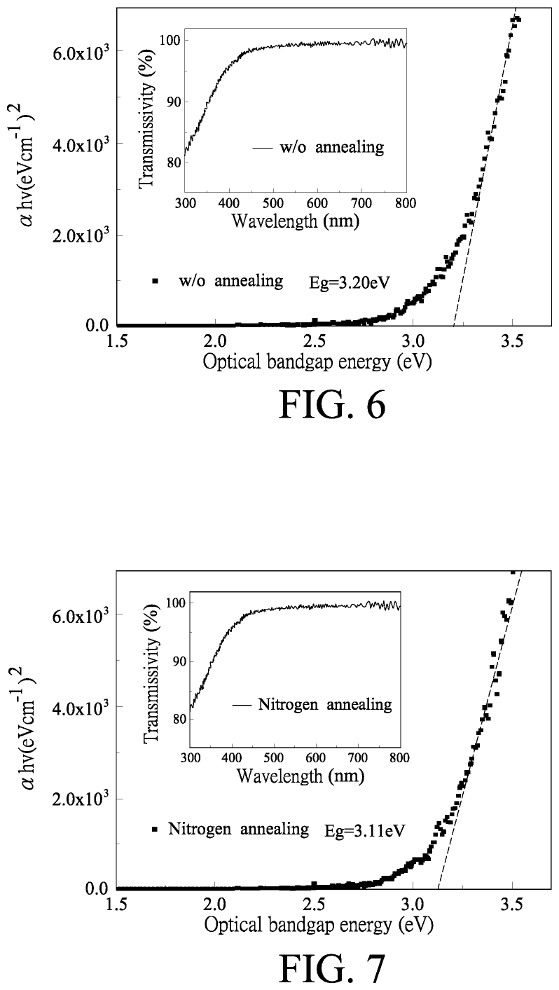

Referring to FIGS. 6 and 7, the effect of nitrogen doping on the bandgap of the sensing channel layer 25 may be determined using a photometer. FIG. 6 is a Tauc plot graph of optical bandgap energy of the sensing channel layer 25 without nitrogen doping, and FIG. 7 is a Tauc plot graph of the optical bandgap energy of the sensing channel layer 25 with nitrogen doping. It can be seen from FIG. 7 that after the sensing channel layer 25 was annealed by nitrogen, changes happened to oxygen vacancies and the defects within the indium zinc oxide material. Since bonding ability of nitrogen is weaker relative to oxygen vacancies, after annealing, the quantity of defects within the thin film may increase, and the bandgap measurement results show that the bandgap of the indium zinc oxide film annealed by nitrogen was smaller. Therefore, the probability of exciting electrons to form a photocurrent under a same incident light is greater, thereby increasing the sensitivity of the photosensitive device to visible light. The responsivity of the transparent thin film transistor-based photosensitive device manufactured in the present embodiment may reach 5600 A/W for a power flux density of 40-120 μW/cm², and the signal-to-noise ratio of the transparent thin film transistor-based photosensitive device is 2.75×10⁸.

Finally, the source electrode 26 and the drain electrode 27 formed on the two opposite end portions of the sensing channel layer 25 may each include metal, metal compound, metal nitride, e.g., molybdenum (Mo), titanium (Ti), palladium (Pd), tungsten (W), cobalt (Co), chromium (Cr), copper (Cu), nickel (Ni), tantalum (Ta), platinum (Pt), gold (Au), aluminum (Al), tungsten titanium (TiW), titanium nitride (TiN), tantalum nitride (TaN), etc. In this embodiment, each of the source electrode 26 and the drain electrode 27 is made of molybdenum (Mo).

In summary, in the method of manufacturing the transparent thin film transistor-based photosensitive device of the present disclosure, indium zinc oxide is used in forming the sensing channel layer 25, which is doped with nitrogen by being subjected to nitrogen annealing, so that the sensitivity of the photosensitive device to visible light (in particular, blue light and green light) is increased, and that the photosensitive device may be used under low lighting conditions for applications such as in-display fingerprint readers. In addition, by using the high dielectric constant material for forming the gate insulator layer 24, control ability of the gate electrode layer 23 is increased and characteristics of the gate electrode layer 23 is stabilized after being scaled, so that the operating voltage (i.e., voltage of the gate electrode layer 23) of the photosensitive device may be reduced to a range of −3V to 4V, thereby reducing its power consumption. By embedding the transparent thin film transistor-based photosensitive device of the present disclosure in a display panel, problems such as high power consumption may be solved and the responsivity and signal-noise-ratio of the photosensitive device may be increased, so that even under low lighting conditions, the photosensitive device embedded in an in-display fingerprint reader may still function after being scaled. Furthermore, the method is conducted at the temperature lower than 250° C., which meets the limited budget requirement for thermal processing a flexible substrate, and may be applied to a photosensitive device with a curved surface. Thus, the purpose of the disclosure is achieved.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A method for manufacturing a transparent thin film transistor-based photosensitive device, comprising:
preparing a semiconductor substrate unit including a gate electrode layer;
forming a gate insulator layer by depositing a high dielectric constant material using plasma-assisted atomic layer deposition to cover the gate electrode layer;
forming a sensing channel layer made of an indium oxide-based material on the gate insulator layer in a position corresponding to the gate electrode layer by sputtering, and doping nitrogen into the sensing channel layer; and
forming a source electrode and a drain electrode on two opposite end portions of the sensing channel layer, respectively.

2. The method as claimed in claim 1, wherein the sensing channel layer is doped with nitrogen by in-situ introduction of nitrogen when the sensing channel layer is formed.

3. The method as claimed in claim 1, wherein the sensing channel layer is doped with nitrogen by subjecting the sensing channel layer to nitrogen annealing after being formed.

4. The method as claimed in claim 1, wherein the gate insulator layer includes hafnium dioxide, aluminum oxide, zirconium dioxide, hafnium zirconium oxide, titanium dioxide, tantalum pentoxide, or combinations thereof.

5. The method as claimed in claim 1, wherein the sensing channel layer includes amorphous indium oxide, amorphous indium zinc oxide, amorphous indium tungsten oxide, amorphous indium tungsten zinc oxide, amorphous indium tin oxide, amorphous indium tin zinc oxide, or combinations thereof.

6. The method as claimed in claim 1, wherein the gate insulator layer includes hafnium dioxide.

7. The method as claimed in claim 6, wherein the sensing channel layer is formed by an indium zinc oxide target through sputtering deposition, the indium zinc oxide target having a ratio of In₂O₃ to ZnO 9:1.

8. The method as claimed in claim 1, further comprising subjecting each of the gate insulator layer and the sensing channel layer to supercritical carbon dioxide fluid technology to enhance a dielectric property thereof.

9. The method as claimed in claim 1, wherein the sensing channel layer has a thickness ranging from 2 nm to 10 nm.

10. The method as claimed in claim 1, wherein the semiconductor substrate unit further includes a substrate and a buffer layer disposed on the substrate, the gate electrode layer being disposed on the buffer layer.
